(19) United States
(12) Patent Application Publication
(10) Pub. No.: US 2008/0206943 A1
(43) Pub. Date: Aug. 28, 2008

(54) METHOD OF FORMING STRAINED CMOS TRANSISTOR

(76) Inventors: Jei-Ming Chen, Taipei Hsien (TW); Neng-Kuo Chen, Hsin-Chu City (TW); Hsiu-Lien Liao, Tai-Chung City (TW); Teng-Chun Tsai, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/679,132

(22) Filed: Feb. 26, 2007

(51) Int. Cl. H01L 21/8238

(52) U.S. Cl. 438/229; 257/E21.623

(57) ABSTRACT

A method of fabricating CMOS transistor is disclosed. Initially, a semiconductor substrate having at least a first active area and a second active area is provided. A high-strained thin film is formed on the semiconductor substrate, the first active area, and the second active area. Thereafter, a mask is formed to cover a part of the high-strained thin film, which is disposed on the first active area. An implantation is performed to implant dopants into the part of the high-strained thin film on the second active area and to modify the stress status thereof. After that, the mask is removed and a rapid thermal annealing process is performed. Then, the high-strained thin film is removed and the method of the present invention is accomplished.

### BACKGROUND OF THE INVENTION

1. Field of the Invention

The present invention is related to a method of forming a strained CMOS transistor, especially to a method including steps of forming a high-strained thin film on the CMOS transistor and performing an implantation process to modify the stress status of the high-strained thin film that improves the performance of the strained CMOS transistor.

2. Description of the Prior Art

The industrial circles are used to reducing device dimensions to improve the performance of MOS transistors. However, this method encounters great difficulties with high-expenses and technical bottlenecks in recent years. For these reasons, the industrial circles seek other methods to improve MOS transistor performance. And accordingly, a highly noticed method is to utilize the material characteristics to cause strain effect on MOS transistors.

The industrial circles develop a strained-silicon technique, which uses unique processes or lattice constant discrepancy to increase driving current. The strained-silicon technique substantially includes a substrate-strained based method and a process-induced strain based method. The substrate-strained based system is performed with a strained-silicon substrate or a selective epitaxial growth process that results in lattice constant discrepancy. The process-induced strain based method is performed with several unique processes to form a strained thin film upon a surface of the MOS transistor that exert tensile stress or compressive stress upon the MOS transistor. The process-induced strain based method introduces strain into the channel region, which can reduce carrier mobile resistance thereby improving carrier mobility and MOS transistor performance.

During the deep submicron process, the industry circles usually cover a high-tensile thin film on a CMOS transistor including a PMOS transistor and a NMOS transistor, such as a cap poly stressor, or a contact etch stop (CESL) layer, which introduces a tensile stress to the PMOS transistor and the NMOS transistor to improve their performance simultaneously. The high tensile thin film elongates the distance of lattice in the channel region, thereby improving electrons mobility and NMOS transistor performance. The method of covering the tensile thin film on the CMOS transistor certainly improves NMOS transistor performance. However, the tensile stress applied to the PMOS transistor neither improves PMOS transistor performance nor increases driving current of the PMOS transistor. In fact, the tensile stress damages the PMOS transistor. Although the high-tensile thin film certainly improves NMOS transistor performance, the high-tensile thin film damages the PMOS transistor. The conventional method of inducing strain in to the channel region faces the dilemma of improving NMOS transistor performance or PMOS transistor performance.

For the reasons above, the industry circles try to develop a method of strained-silicon technique to fabricate CMOS transistors and improve CMOS transistor reliability.

### SUMMARY OF THE INVENTION

The following presents a simplified summary in order to provide a basic understanding of one or more aspects of the invention, this summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The primary objective of the present invention is to provide a method of fabricating a strained CMOS transistor to improve CMOS transistor performance and reliability and to overcome the drawback of conventional techniques.

Accordingly, the present invention provides a method of fabricating a strained CMOS transistor that includes following steps. Initially, a semiconductor substrate is provided. The semiconductor substrate has at least a first active area and at least a second active area. A high-strained thin film is formed to cover the semiconductor substrate, the first active area, and the second active area. And then a mask is formed to cover the first active area. An implantation process is performed to implant dopants into a part of the high-strained thin film on the second active area not protected by the mask and to modify the stress status of the high-strained thin film on the second active area. The mask is removed and a rapid thermal annealing process is performed. After that, the high-strained thin film is removed and the method of the present invention is accomplished.

Furthermore, the present invention further provides a method of fabricating a strained CMOS transistor that includes following steps. Initially, a semiconductor substrate is provided. The semiconductor includes at least a N-well and at least a P-well. The N-well has at least a gate disposed thereon and the N-well has at least a gate disposed thereon. A high-tensile thin film is formed to cover the semiconductor substrate, the N-well, and the P-well. A mask is formed to cover the N-well. An implantation process is performed to implant dopants into a part of the high-tensile thin film on the P-well not protected by the mask and to reduce the stress status of the high-tensile thin film on the P-well. The mask is removed and a rapid thermal annealing process is performed. After that, the high-tensile thin film is removed and the method of the present invention is accomplished.

Moreover, the present invention further provides a method of fabricating a strained CMOS transistor that includes following steps. Initially, a semiconductor substrate is provided. The semiconductor includes at least a N-well and at least a P-well. The N-well has at least a gate disposed thereon and the N-well has at least a gate disposed thereon. A high-compressive thin film is formed to cover the semiconductor substrate, the N-well, and the P-well. A mask is formed to cover the P-well. An implantation process is performed to implant dopants into a part of the high-compressive thin film on the N-well not protected by the mask and to reduce the stress status of the high-compressive thin film on the P-well. The mask is removed and a rapid thermal annealing process is performed. After that, the high-compressive thin film is removed and the method of the present invention is accomplished.

Specifically, the method of the present invention not only improves the carrier mobility of CMOS transistor, but also improves CMOS transistor performance. The method of the present invention also has advantages of being capable of integrating into the semiconductor processes, capable of incorporating with other strained-silicon processes, and capable of improving CMOS transistor reliability.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 7 are schematic diagrams illustrating a method of fabricating a strained CMOS transistor according to a first embodiment of the present invention.

FIG. 8 to FIG. 11 are schematic diagrams illustrating a method of fabricating a strained CMOS transistor according to a second embodiment of the present invention.

FIG. 12 is a flow diagram illustrating a method of fabricating a strained CMOS transistor in accordance with the third embodiment of the present invention.

### DETAILED DESCRIPTION

In the following detailed description, reference is made to the accompanying drawings, which form a part of this application. The drawings show, by way of illustration, specific embodiments in which the invention may be practiced. It is to be understood that other embodiments may be utilized and structural changes may be made without departing from the scope of the present invention.

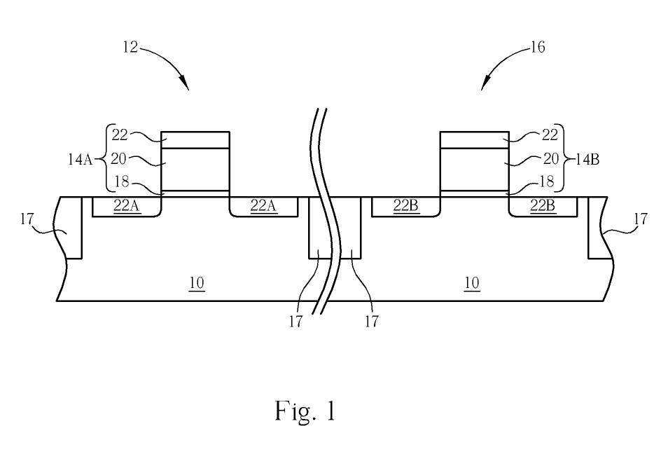

Please refer to FIG. 1 to FIG. 7, which are schematic diagrams illustrating a method of fabricating a strained CMOS transistor according to a first embodiment of the present invention. As shown in FIG. 1, a semiconductor substrate 10 is provided. The semiconductor substrate 10 may comprise a silicon substrate, a strained-silicon substrate, a compound semiconductor substrate, a silicon-on-insulator (SOI) substrate or combinations thereof. Those skilled in the art may use methods, such as forming a mask, performing an ion implantation, and performing a rapid thermal annealing (RTA) process to form a plurality of P-wells and a plurality of N-wells on the semiconductor substrate 10. In addition, the semiconductor substrate has a plurality of MOS transistors disposed on the P-wells and the N-wells respectively, for instance, a gate structure 14A of a PMOS transistor 12 and a gate structure 14B of a NMOS transistor 16; and a plurality of isolation structures between the MOS transistors to prevent short circuiting, such as a field oxide layer (not shown) or a shallow trench isolation 17. Each gate structure 14A, 14B includes a gate dielectric layer 18, a gate 20, and a cap layer 22. The gate dielectric layer 18 may comprise silicon oxide, oxynitride, silicon nitride, or combinations thereof. The gate dielectric layer 18 may be formed by a thermal oxidation process, a nitridation process, or a chemical vapor deposition process. The gate 20 may comprise polysilicon, SiGe, metal, silicide, metal nitride, or metal oxide. In addition, lightly doped drains (LDD) 22A, 22B are formed in the semiconductor substrate 10 next to the gate structure 14A, 14B. The function of the LDDs 22A, 22B is to prevent hot electron effects of PMOS transistor 12 or NMOS transistor 16.

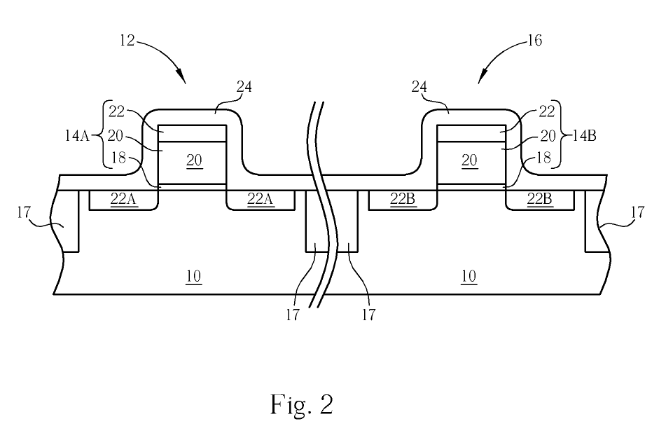

As shown in FIG. 2, a deposition process is performed by using a furnace or a CVD process to form a high-tensile thin film 24 covering the PMOS transistor 12, the NMOS transistor 16, and the semiconductor substrate 10. The high-tensile thin film 24 may comprise silicon nitride, silicon oxide, or oxynitride. The preferred high-tensile thin film 24 is formed by a plasma-enhanced CVD (PECVD) process under suitable frequency and working condition to deposit a silicon nitride thin film, which a SiN thin film is preferred. The preferred temperature of forming the high-tensile thin film 24 is between 200 degrees C. and 450 degrees C. The high-tensile thin film 24 has a stress status approximately at 0.7 GPa and a depth between 100 angstroms (Å) and 600 Å. The preferred depth of the high-tensile thin film 24 is approximately at 500 Å. In addition, an ultra violet rapid thermal process may be performed selectively to cure the high-compressive thin film 24 and modify the stress status of the high-compressive thin film 36 to approximately 1.5 GPa.

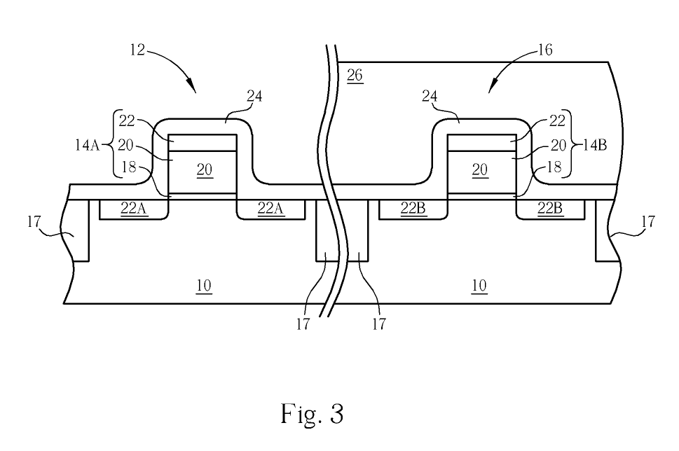

As shown in FIG. 3, a mask 26 is formed on a surface of the high-tensile thin film 24. In the first embodiment, the mask 26 is formed by coating photoresist on the surface of the high-tensile thin film 24. Thereafter, an exposing and developing process is performed to remove a part of the photoresist on the PMOS transistor 12 and preserve the photoresist on the NMOS transistor 16 that is used as a mask during following processes.

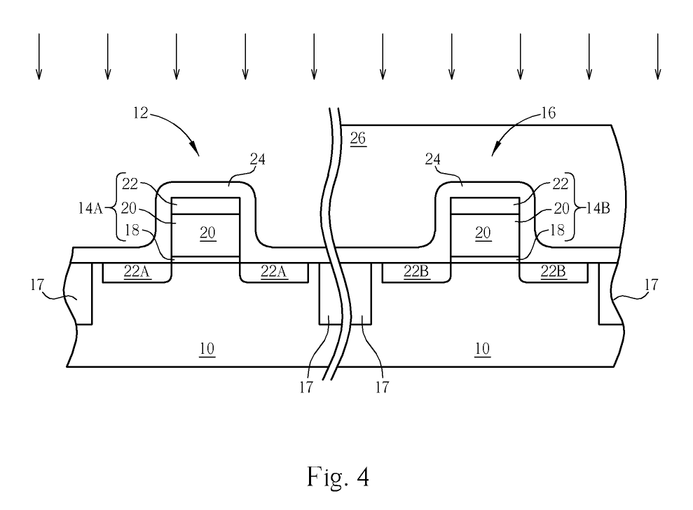

Referring to FIG. 4, a first implantation process is performed to implant dopants into the high-tensile thin film 24 on the PMOS transistor 12 not covered by the mask 26 and to modify the stress status thereof. The preferred implantation energy is approximately 50 KeV, and the preferred implant dosage is approximately 3.15×10¹⁵ ion/cm². The dopants may include germanium, arsenic, xenon, indium, antimony, silicon, sulfur, nitrogen, oxygen, copper or fluorine. In addition, the first implantation process may be a co-implantation process to implant at least two species of the above-mentioned elements into the high-tensile thin film 24 on the PMOS transistor 12. The high-tensile thin film 24 on the PMOS may have a reduced stress status of approximately 0.1 GPa to 0.2 GPa.

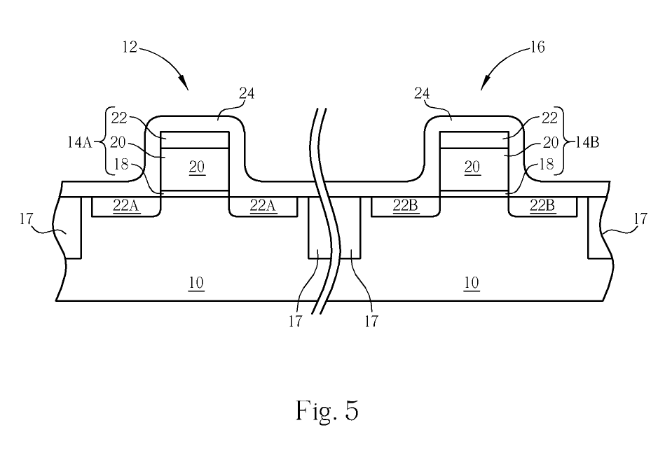

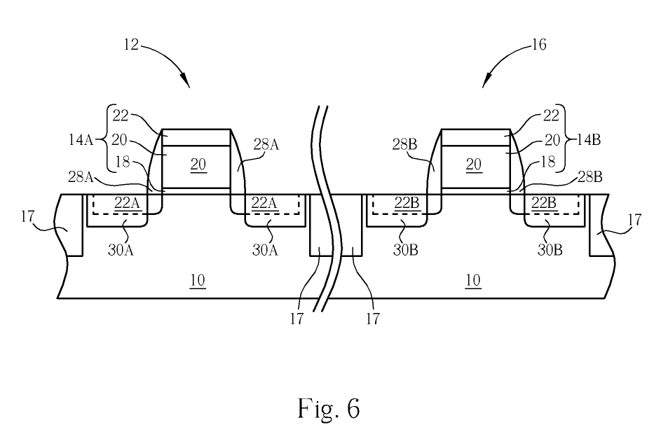

As shown in FIG. 5, the mask 26 is removed and a RTA process is performed after the first implantation process. The RTA process is performed using a furnace or a rapid thermal process to introduce strain into the lattice of the channel under the gate structures 14A, 14B at approximately 800 degrees C. to 1200 degrees C., and is preferably performed at 1050 degrees C. In addition, helium may be added during the RTA process. As shown in FIG. 6, an etch back process is performed to remove most of the high-tensile thin film 24 and preserve a part of the high-tensile thin film 24 next to the gate structures 14A, 14B, which forms spacers 28A, 28B. Thereafter, a second implantation process is performed to form predetermined regions of source/drain aside the spacer 28A of the PMOS transistor 12 and the spacer 28B in the semiconductor substrate 10. Additionally, the implantation is preferably performed twice time, and dosages for the source/drain aside the spacer 28A of the PMOS transistor 12 and the spacer 28B may be different. And then, another RTA process is performed and a source/drain 30A of the PMOS transistor 12 and a source/drain 30B of the NMOS transistor 16 are formed. Furthermore, a self-aligned silicide (salicide) process is performed to form silicide at the surface of the gate structures 14A, 14B or the surface of the sources/drains 30A, 30B. The processes are well known to those skilled in the art and the details are abridged.

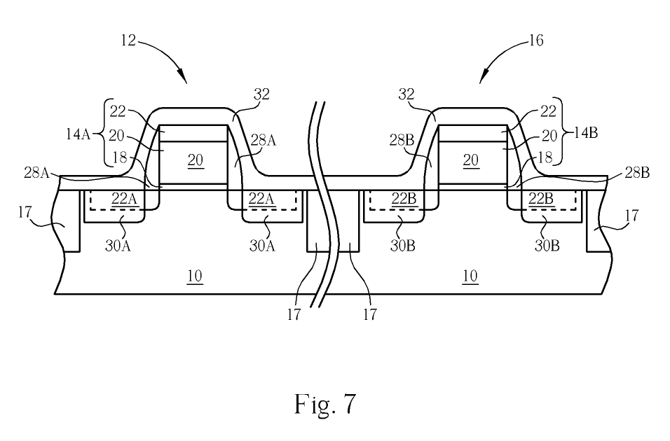

As shown in FIG. 7, a PECVD process is performed to form a CESL layer 32 on the surface of the gate structures 14A, 14B, the spacers 28A, 28B, and the sources/drains 30A, 30B. The CESL 32 has a depth between 800 Å and 1100 Å. Additionally, an inter-layer dielectric (ILD) layer (not shown) and a patterned photoresist (not shown) may be formed. An anisotropic etching process may be performed using the patterned photoresist as an etching mask to form a plurality of contact holes (not shown) in the ILD layer and the CESL layer 32. The contact holes are the connections between the gates 14A, 14B or the sources/drains 30A, 30B with other electrical devices.

Comparing the conventional method, the method of the present invention is performed before the salicide process. The high-tensile thin film on the NMOS maintains the stress status of 1.5 GPa and introduces a tensile stress to the channel of the NMOS transistor thereby improving NMOS transistor performance. On the other hand, the high-tensile thin film on the PMOS transistor has a much lower stress status of approximately 0.19, which is reduced by the implantation process. The high-tensile thin film has such a low stress status having no negative effects upon the PMOS transistor, or damaging the PMOS transistor. In addition, the high-tensile thin film of the present invention is removed from the surface of the CMOS transistor after it introduces the tensile stress to the channel of the NMOS transistor. Thus, the high-tensile thin film can be regarded as a sacrificial layer.

The first embodiment has a high-tensile thin film deposited on the surface of the CMOS transistor without spacers. In order to improve NMOS performance without damaging the PMOS transistor, a sequence of steps are performed, including an implantation process, an RTA process to improve carrier mobility of the NMOS transistor, and an etching process partially etching the high-tensile thin film to form the spacers of the CMOS transistor. In addition, the high-strained thin film may also improve PMOS transistor performance that deposits a high-compressive thin film on the CMOS with spacers and performs the following processes. The detail description will be illustrated as follows.

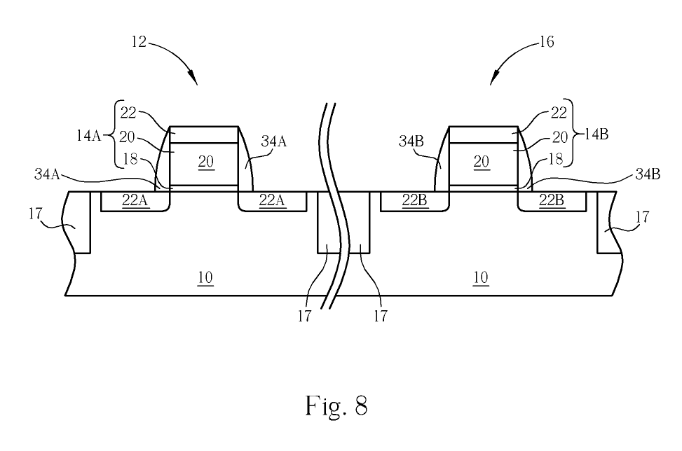

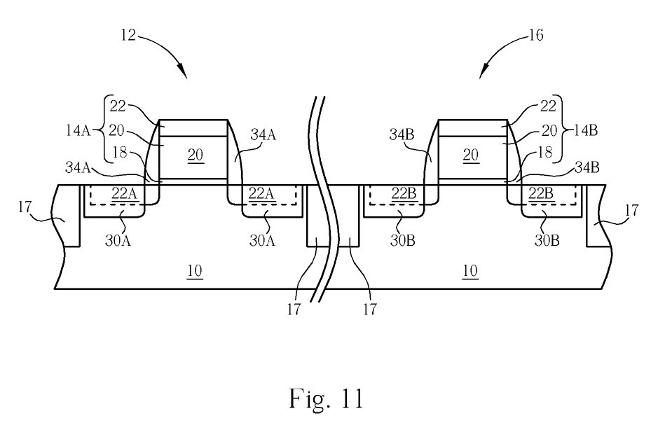

Please refer to FIG. 8 to FIG. 11, which are schematic diagrams illustrating a method of fabricating a strained CMOS transistor according to a second embodiment of the present invention. Some elements are the same as those of the first embodiment and are numbered as those of the first embodiment. Referring to FIG. 8, a semiconductor substrate 10 is provided. The semiconductor substrate 10 has a plurality of P-wells and a plurality of N-wells defined therein. The semiconductor substrate 10 further comprises a plurality of MOS transistors disposed in the N-wells and the P-wells, respectively. For instance, a gate structure 14A of a PMOS transistor 12 is disposed in the P-well and a spacer 34A is located aside the gate structure 14A. A gate structure 14B of a NMOS transistor 16 is disposed in the N-well and a spacer 34B is located aside the gate structure 14B. A plurality of isolation structures is disposed between the PMOS transistors and NMOS transistors to prevent short circuiting, such as a field oxide layer (not shown) or a shallow trench isolation 17. Each gate structure 14A, 14B includes a gate dielectric layer 18, a gate 20, and a cap layer 22. In addition, LDDs 22A, 22B are formed in the semiconductor substrate 10 next to the gate structure 14A, 14B. The function of the LDDs 22A, 22B is to prevent hot electron effects of the PMOS transistor 12 or NMOS transistor 16.

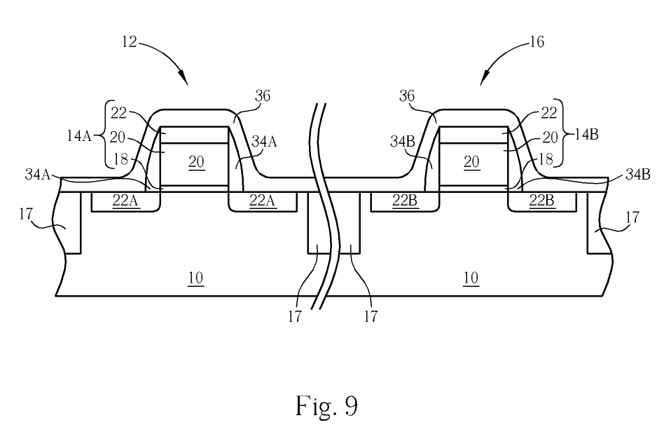

As shown in FIG. 9, a deposition process is performed by using a furnace or a CVD process to form a high-compressive thin film 36 covering the PMOS transistor 12, the NMOS transistor 16, and the semiconductor substrate 10. The high-compressive thin film 36 may comprise silicon nitride, silicon oxide, or oxynitride. The preferred high-compressive thin film 36 is formed by a PECVD process under suitable frequency and working condition to deposit a silicon nitride thin film, which a SiN thin film is preferred. The preferred temperature of forming the high-tensile thin film 24 is between 200 degrees C. and 450 degrees C. The high-compressive thin film 36 has a depth between 100 Å and 600 Å, and 500 Å is preferred. In addition, an ultra violet rapid thermal process may be performed selectively to cure the high-compressive thin film 36 and modify the stress status of the high-compressive thin film 36.

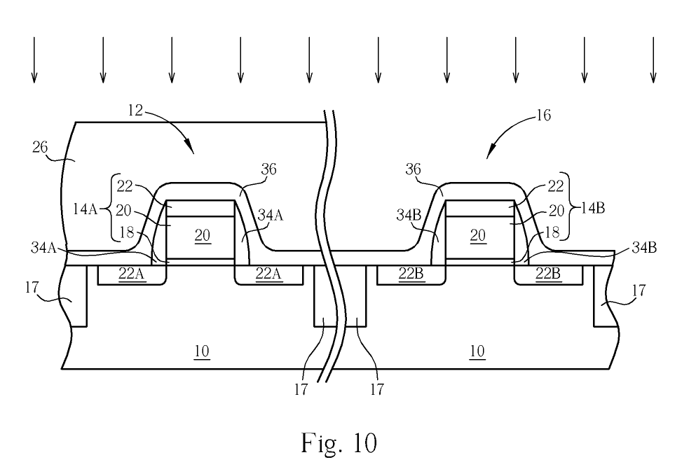

As FIG. 10 shows, a mask 26 is formed on a surface of the high-compressive thin film 36. The high-compressive thin film 36 covers a part of the high-compressive thin film 36 on the PMOS transistor 12 and exposes the high-compressive thin film 36 on the NMOS transistor 16. Thereafter, a first implantation process is performed to implant dopants into the high-compressive thin film 36 on the PMOS transistor 12 not covered by the mask 26 and to modify the stress status thereof. The dopants may include germanium, arsenic, xenon, indium, antimony, silicon, sulfur, nitrogen, oxygen, copper or fluorine. In addition, the first implantation process may be a co-implantation process to implant at least two species of the above-mentioned elements into the high-compressive thin film 36 on the PMOS transistor 12. The compressive stress of the high-compressive thin film 36 on the PMOS may be released by the first implantation process or the co-implantation process.

Referring to FIG. 1, the mask 26 is removed and a RTA process is performed after the first implantation process. The RTA process is performed using a furnace or a rapid thermal process to introduce strain into the lattice of the channel under the gate structures 14A, 14B at approximately 800 degrees C. to 1200 degrees C., and is preferably performed at 1050 degrees C. And then, an etch back process is performed to remove most of the high-compressive thin film 36. The following steps of fabricating follows the steps performed in the first embodiment. For instance, a second implantation process and another RTA process are performed to form a source/drain 30A of the PMOS transistor 12 and a source/drain 30B of the NMOS transistor 16. Furthermore, several steps are performed, including a salicide process, a deposition process forming a CESL layer (not shown) and an ILD layer (not shown), forming a patterned photoresist (not shown), and performing an anisotropic etching step to form contact holes (not shown). The details of the steps are illustrated as the first embodiment.

The second embodiment utilizes the implantation process to implant dopants into the high-compressive thin film on the NMOS transistor that release the compressive stress thereof. The released compressive thin film will not damage to the NMOS transistor. Additionally, the high-compressive thin film on the PMOS transistor maintains the stress status after the implantation process and the RTP process and thereby improves PMOS transistor performance. The method of the present invention successfully solves the dilemma of improving PMOS performance or improving NMOS performance, which are caused by using a thin film only having a compressive stress status.

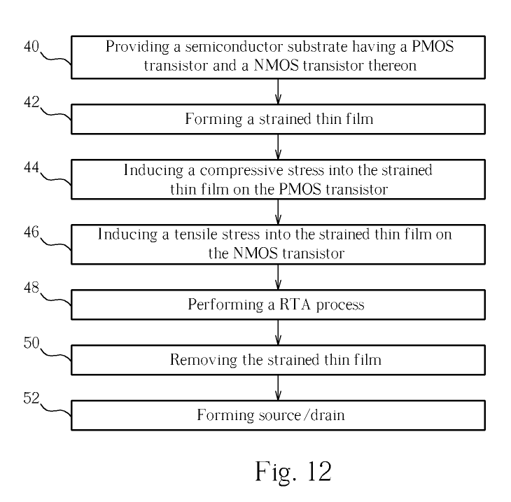

Therefore, the method of the present invention utilizes the implantation process to modify the stress status of the high-strained thin film that introduces different stress into the PMOS transistor and the NMOS transistor thereby improving performance of PMOS transistor and the NMOS transistor. Accordingly, a third embodiment of the present invention is disclosed. Please refer to FIG. 12, which is a flow diagram illustrating a method of fabricating a strained CMOS transistor in accordance with the third embodiment of the present invention. The steps of the third embodiment are illustrated as follows.

Step 40: A semiconductor substrate having at least a PMOS transistor and at least a NMOS transistor is provided.

Step 42: A deposition process is performed to form a stress-less thin film, such as a SiN thin film, on the PMOS transistor and the NMOS transistor.

Step 44: A first patterned mask is formed on the SiN thin film to cover the NMOS transistor, and the patterned mask functions as a mask during the following implantation process. Afterward, a first implantation process is performed to implant dopants into the SiN film on the PMOS transistor not covered by the first patterned mask thereby modifying the stress status of the SiN film on the PMOS transistor into a compressive stress. And then, the first patterned mask is removed.

Step 46: A second patterned mask is formed on the SiN thin film to cover the PMOS transistor, and the patterned mask functions as a mask during the following implantation process. Afterward, a second implantation process is performed to implant dopants into the SiN film on the NMOS transistor not covered by the second patterned mask thereby modifying the stress status of the SiN film on the NMOS transistor into a tensile stress. And then, the second patterned mask is removed.

Step 48: An RTA process is performed to introduce strain into the lattice of the channel under the gate structures 14A, 14B. At this moment, the stress-less SiN thin film has a compressive stress on the PMOS transistor and a tensile stress on the NMOS transistor. That means, the same SiN thin film has different types of stress upon different regions depending on the type of the MOS transistor that the SiN film covers on.

Steps 50: The SiN thin film is removed.

Step 52: A third implantation process is performed to form sources/drains next to the PMOS transistors and the NMOS transistor.

After the source/drain is formed, several steps may be performed as the prior embodiments show. The steps are the salicide process, the deposition process to form the CESL layer and the ILD layer, forming the patterned photoresist, and the anisotropic etching process to form the contact holes. The details of the steps are illustrated as with the prior embodiments. The third embodiment of the present invention combines the first embodiment and the second embodiment to perform an implantation process specifically to the strained thin film on the PMOS transistor or that on the NMOS transistor. And accordingly, the strained thin film on the PMOS transistor has a compressive stress, and the strained thin film on the NMOS transistor has a tensile stress. In addition, the sequence of the implantation processes may be reversed. The implantation process for the strained thin film on the NMOS may be performed before the implantation process for the strained thin film on the PMOS.

The method of the present invention may also incorporate with other strained-silicon techniques, such as an epitaxial growth process, and a dual CESL process. Take the first embodiment of the present invention as an example. After performing the method of the present invention, NMOS transistor performance is improved. Afterward, one of the following processes may be performed on the CMOS transistor of the first embodiment that additionally introduces strain into the NMOS transistor or the PMOS transistor. The following processes are:

Process A: forming a dual CESL layer. A tensile thin film is formed on the NMOS transistor, and a compressive thin film is formed on the PMOS transistor. The dual CESL layer may introduce a tensile stress into the channel of the NMOS transistor and a compressive stress into the channel of the PMOS transistor, respectively.

Process B: forming a tensile CESL layer on the NMOS transistor and forming epitaxial layers aside the gate structure of the PMOS transistor. Initially, a plurality of trenches are formed aside the gate structures of the PMOS transistor. And a plurality of epitaxial layers is formed in the trenches, such as SiGe epitaxial layers. Since the SiGe epitaxial layer has different lattice constant from the semiconductor substrate, the SiGe epitaxial layer will introduce a compressive stress into the channel of the PMOS transistor.

Process C: forming a compressive CESL layer on the PMOS transistor and forming epitaxial layers aside the gate structure of the NMOS transistor. Initially, a plurality of trenches are formed aside the gate structures of the NMOS transistor. And a plurality of epitaxial layers is formed in the trenches, such as SiC epitaxial layers. Since the SiC epitaxial layer has a different lattice constant from the semiconductor substrate, the SiC epitaxial layer will introduce a tensile stress into the channel of the PMOS transistor.

Process D: forming a compressive CESL layer covering the PMOS transistor that introduces a compressive stress into the channel of the PMOS transistor.

When incorporating the method of the present invention with conventional CESL process, the depth of the CESL layer may be substantially reduced, which prevents cracks resulting from the CESL layer having a greater depth. In addition, the following etching process of forming the contact holes may have better etching rate.

In conclusion the method of the present invention forms a high-strained thin film on the PMOS transistor and the NMOS transistor and uses an implantation process and the mask to implant dopants into one of the MOS transistors not covered by the mask and modify the stress status thereof. And eventually, the high-strained thin film is removed. In addition, the method of the present invention may incorporate with other kinds of strained-silicon process, such as forming an epitaxial layer or a CESL layer, to improve the performance of the PMOS transistor and the NMOS transistor simultaneously.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a strained CMOS transistor, comprising:
providing a semiconductor substrate, the semiconductor substrate including at least a first active area and at least a second active area;
forming a high-strained thin film covering the semiconductor substrate, the first active area, and the second active area;
forming a mask covering the first active area;
performing an implantation process to implant dopants into a part of the high-strained thin film on the second active area;
removing the mask;
performing a rapid thermal annealing process; and
removing the high-strained thin film.

2. The method of claim 1, wherein the first active area comprises a gate of a NMOS transistor, and the second active area comprises a gate of a PMOS transistor.

3. The method of claim 1, wherein the first active area comprises a gate of a PMOS transistor, and the second active area comprises a gate of a NMOS transistor.

4. The method of claim 1, further comprising a lightly doped drain disposed aside the gate in the first active area and in the second active area, respectively.

5. The method of claim 1, further comprising an ultra violet rapid thermal process to cure the high-strained thin film after the high-strain thin film is formed.

6. The method of claim 1, wherein the high-strained thin film is partially removed, and a part of the high-strained thin film is preserved to form a spacer in the first active area and a spacer in the second active area, respectively.

7. The method of claim 1, wherein the dopants used in the implantation process comprise germanium, arsenic, xenon, indium, antimony, silicon, sulfur, nitrogen, oxygen, copper or fluorine.

8. The method of claim 7, wherein the implantation process is performed with an implant energy of approximately 50 KeV, and an implant dosage of approximately 3.15×10¹⁵ ion/cm².

9. The method of claim 1, wherein the rapid thermal annealing process is performed at approximately between 800 degrees C. and 1200 degrees C.

10. The method of claim 1, wherein the rapid thermal annealing process is performed at approximately 1050 degrees C.

11. The method of claim 1, wherein the high-strained thin film has a stress status of approximately between −3.0 Gpa and 2.0 Gpa.

12. The method of claim 1, further comprising performing a self-aligned silicide process after the high-strain thin film is removed.

13. The method of claim 1, further comprising a deposition process to form a contact etch stop layer covering the semiconductor substrate, the first active area, and the second active area after the high-strain thin film is removed.

14. A method of forming a strained CMOS transistor, comprising:
providing a semiconductor substrate, the semiconductor substrate including at least a N-well and at least a P-well, and accordingly, at least a gate disposed upon the N-well and at least a gate disposed upon the P-well;
forming a high-tensile thin film covering the semiconductor substrate, the N-well, and the P-well;
forming a mask covering the N-well;
performing an implantation process to implant dopants into a part of the high-tensile thin film on the P-well;
removing the mask;
performing a rapid thermal annealing process; and
removing the high-tensile thin film.

15. The method of claim 14, wherein the N-well and the P-well further comprise a spacer on a sidewall of the gate and a light doped drain aside the gate in the N-well and the P-well, respectively.

16. The method of claim 14, further comprising an ultra violet rapid thermal process to cure the high-tensile thin film after the high-tensile thin film is formed.

17. The method of claim 14, wherein the dopants used in the implantation process comprise germanium, arsenic, xenon, indium, antimony, silicon, sulfur, nitrogen, oxygen, copper or fluorine.

18. The method of claim 17, wherein the implantation process is performed with an implant energy of approximately 50 KeV, and an implant dosage of approximately 3.15×10¹⁵ ion/cm².

19. The method of claim 14, wherein the rapid thermal annealing process is performed at approximately between 800 degrees C. and 1200 degrees C.

20. The method of claim 14, wherein the rapid thermal annealing process is performed at approximately 1050 degrees C.

21. The method of claim 14, wherein the high-tensile thin film has a stress status of approximately between −3.0 Gpa and 2.0 Gpa.

22. The method of claim 14, further comprising performing a self-aligned silicide process after the high-tensile thin film is removed.

23. The method of claim 14, further comprising a deposition process to form a contact etch stop layer covering the semiconductor substrate, the N-well, and the P-well after the high-tensile thin film is removed.

24. A method of forming a strained CMOS transistor, comprising:
providing a semiconductor substrate, the semiconductor substrate including at least a N-well and at least a P-well, and accordingly, at least a gate disposed upon the N-well and at least a gate disposed upon the P-well;
forming a high-compressive thin film covering the semiconductor substrate, the N-well, and the P-well;
forming a mask covering the P-well;
performing an implantation process to implant dopants into a part of the high-compressive thin film on the N-well;
removing the mask;
performing a rapid thermal annealing process; and
removing the high-compressive thin film.

25. The method of claim 24, wherein the N-well and the P-well further comprise a spacer on a sidewall of the gate and a light doped drain aside the gate in the N-well and the P-well, respectively.

26. The method of claim 24, further comprising an ultra violet rapid thermal process to cure the high-compressive thin film after the high-compressive thin film is formed.

27. The method of claim 24, wherein the dopants used in the implantation process comprise germanium, arsenic, xenon, indium, antimony, silicon, sulfur, nitrogen, oxygen, copper or fluorine.

28. The method of claim 24, wherein the rapid thermal annealing process is performed at approximately between 800 degrees C. and 1200 degrees C.

29. The method of claim 24, wherein the rapid thermal annealing process is performed at approximately 1050 degrees C.

30. The method of claim 24, wherein the high-compressive thin film has a stress status of approximately between −3.0 Gpa and 2.0 Gpa.

31. The method of claim 24, further comprising performing a self-aligned silicide process after the high-compressive thin film is removed.

32. The method of claim 24, further comprising a deposition process to form a contact etch stop layer covering the semiconductor substrate, the N-well, and the P-well after the high-compressive thin film is removed.
